(19) United States
(12) Patent Application Publication
(10) Pub. No.: US 2025/0098354 A1
(43) Pub. Date: Mar. 20, 2025

(54) SUBSTRATE FOR AN ELECTRONIC DEVICE

(71) Applicant: Apple Inc., Cupertino, CA (US)

(72) Inventors: Henry M. DAGHIGHIAN, Cupertino, CA (US); Patrick Zilaro, San Diego, CA (US); Joel Weiss, San Mateo, CA (US)

(73) Assignee: Apple Inc., Cupertino, CA (US)

(21) Appl. No.: 18/467,041

(22) Filed: Sep. 14, 2023

(51) Int. Cl. H01L 27/146

(52) U.S. Cl. CPC H10F 39/809; H10F 39/802; H10F 39/804; H10F 39/811

(57) ABSTRACT

The present disclosure describes an integrated circuit device that includes a ceramic-based substrate, a stack of layers disposed on the ceramic-based substrate, and electronic elements. The stack of layers includes an insulation layer and a conductive layer having conductive traces. The electronic elements are electrically connected to the conductive layer. The conductive layer is configured to route electrical signals to the electronic elements.

### FIELD

This disclosure relates to a substrate for an electronic device and, more particularly, to a hybrid insulator thin-film and ceramic substrate used for electronic devices.

### BACKGROUND

In the field of electronics, smaller, faster, and less power consuming electronic devices are desirable. Due to physical constraints, it is challenging to design electronic devices that improve the performance in one metric without adversely impacting another metric (e.g., reduced size, more densely packed, ultra-high frequency, and power efficiency). Thus, sacrifices in one or more metrics may be made when designing electronic devices.

### SUMMARY

Embodiments of the present disclosure include an integrated circuit device. The integrated circuit device includes a ceramic-based substrate, a stack of layers disposed on the ceramic-based substrate, and electronic elements. The stack of layers comprises an insulation layer and a conductive layer having conductive traces. The electronic elements are electrically connected to the conductive layer. The conductive layer can route electrical signals to the electronic elements.

Embodiments of the present disclosure include a waveguide device. The waveguide device includes a ceramic-based substrate and a waveguide stack disposed on the ceramic-based substrate. The waveguide stack includes a first layer and a second layer. The first layer includes a first dielectric material. The second layer includes a second dielectric material different from the first dielectric material. The second dielectric material has a refractive index greater than a refractive index of the first dielectric material.

Embodiments of the present disclosure include a method to fabricate a stack of layers on a substrate. The method includes disposing a first conductive layer on a ceramic-based substrate. The method also includes disposing a first silicon dioxide layer on the first conductive layer and etching a trench in the first silicon dioxide layer. The method also includes disposing a conductive material in the trench to form a first conductive trace and disposing a second silicon dioxide layer on the first silicon dioxide layer and the first conductive trace. The method further includes disposing a second conductive layer over the second insulation layer.

### BRIEF DESCRIPTION OF THE DRAWINGS

Embodiments of the present disclosure are best understood from the following detailed description when read with the accompanying figures. It is noted that, according to the standard practice in the industry, various features are not drawn to scale. Features of the present disclosure can be illustrated having larger and/or smaller dimensions for clarity of discussion.

FIG. 1 shows an illustration of an integrated circuit device, according to some embodiments.

FIG. 2 shows an illustration of an on-chip camera, according to some embodiments.

FIGS. 3A and 3B show illustrations of a stack of layers for an integrated circuit device, according to some embodiments.

FIGS. 4A and 4B show illustrations of another stack of layers for an integrated circuit device, according to some embodiments.

FIGS. 5A and 5B show illustrations of electronic elements, according to some embodiments.

FIG. 6 shows an illustration of elements of a noise filter, according to some embodiments.

FIG. 7 shows an illustration of an integrated waveguide device, according to some embodiments.

FIG. 8 shows a flowchart for a method of fabricating a stack of layers on a substrate, according to some embodiments.

FIG. 9 shows an illustration of various exemplary systems or devices that can include the disclosed embodiments.

Illustrative embodiments will now be described with reference to the accompanying drawings. In the drawings, like reference numerals generally indicate identical, functionally similar, and/or structurally similar elements.

### DETAILED DESCRIPTION

The following disclosure provides different embodiments, or examples, for implementing different features of the provided subject matter. Specific examples of components and arrangements are described below to simplify the present disclosure. These are merely examples and are not intended to be limiting. The present disclosure can make use of reoccurring reference numerals and/or letters in the various examples. This repetition is for the purpose of simplicity and clarity and, unless indicated otherwise, does not in itself indicate a limiting relationship between the various embodiments and/or configurations discussed.

It is noted that references in the specification to “one embodiment,” “an embodiment,” “an example embodiment,” and “exemplary” indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

In some embodiments, the terms “about” and “substantially” can indicate a value of a given quantity that varies within 20% of the value (e.g., +1%, +2%, +3%, +4%, +5%, +10%, +20% of the value). These values are merely examples and are not intended to be limiting. The terms “about” and “substantially” can refer to a percentage of the values as interpreted by those skilled in relevant art(s) in light of the teachings herein.

In the description of at least some embodiments herein, enumerative adjectives (e.g., “first,” “second,” “third,” or the like) can be used to distinguishing like elements without establishing an order, hierarchy, quantity, or permanent numeric assignment (unless otherwise noted). For example, the terms “first trace” and “second trace” can be used in a manner analogous to “i^{th} trace” and “j^{th} trace” so as to facilitate identification of two or more traces without specifying a particular order, hierarchy, quantity, or immutable numeric correspondence.

It is to be understood that the phraseology or terminology herein is for the purpose of description and not of limitation, such that the terminology or phraseology of the present specification is to be interpreted by those skilled in relevant art(s) in light of the teachings herein.

The following disclosure describes embodiments directed to material arrangements for a stack of layers on a ceramic-based substrate for electronic applications. In particular, substrates described herein allow for transmission of ultra-high frequency signals, while reducing signal losses and mitigating parasitic effects.

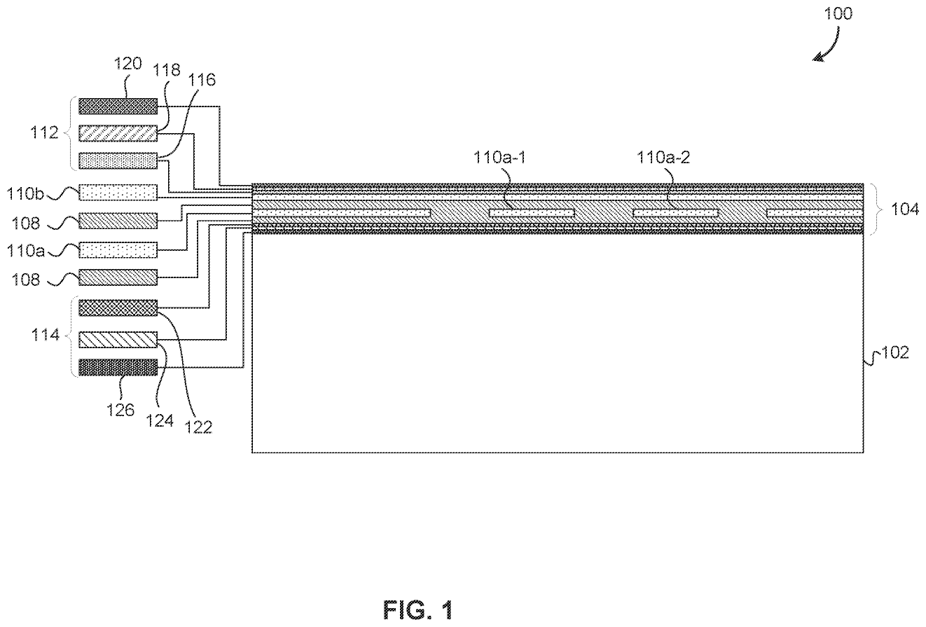

FIG. 1 shows an illustration of an integrated circuit device 100, according to some embodiments. In some embodiments, integrated circuit device 100 includes a substrate 102 and a stack of layers 104. Stack of layers 104 includes an insulation layer 108 and two or more conductive layers 110i (e.g., conductive layers 110a and 110b), where i is an index to represent one or more conductive layers. Each of conductive layers 110i includes two or more conductive traces 110i-j (e.g., conductive traces 110a-1 and 110a-2), where the index i is as before, and j is an index to represent one or more conductive traces.

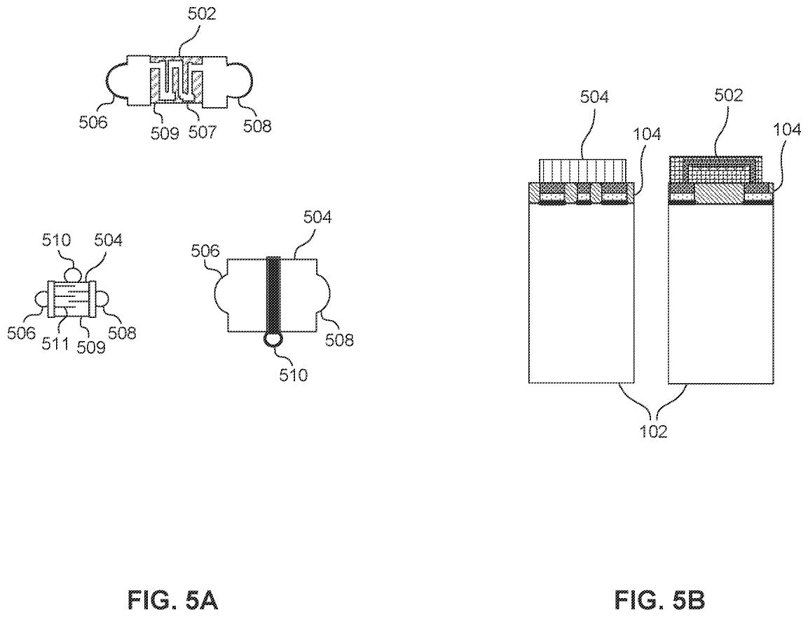

In some embodiments, stack of layers 104 is disposed on substrate 102. One or more of the conductive layers 110i are disposed within insulation layer 108. One or more of conductive layers 110i can be electrically connected to electronic elements. Electronic elements can include those described in reference to FIGS. 5A and 5B (e.g., resistors, capacitors, inductors, transistors, diodes, ferrites/multiferroics, passive devices, and active devices). Conductive layers 110i are configured to route electrical signals to (and/or from) the electronic elements.

In some embodiments, adjusting the mechanical and/or electrical properties of integrated circuit device 100 can involve tradeoffs in various performance metrics, such as device size, data transmission rate (e.g., operational frequencies), signal losses at the operational frequencies, parasitic effects, and fabrication costs. In some embodiments, integrated circuit device 100 is part of an on-chip digital camera (e.g., with high resolution and high framerate) with one or more electronic elements including an array of photodetectors. High definition images captured at tens of frames per second can generate a data stream in the tens of gigabits per second (Gb/s). The operational frequencies for supporting, for example, a 50 Gb/s to 80 Gb/s data stream can result in considerable signal losses. A solution can be to implement additional electronic elements for signal conditioning (e.g., for amplification and signal cleanup) with a special, higher cost substrate (e.g., gold plated low temperature co-fired ceramic (LTCC)). But, the presence of additional circuitry is counter to size reduction goals and also uses power (reduces power efficiency) and generates excess heat. Addressing the above challenges, the present disclosure includes substrate parameters that result in integrated circuits capable of hosting densely packed electronic structures that perform at ultra-high frequencies with low losses and low parasitic effects, and that use low-cost materials and fabrication processes.

Referring to FIG. 1, in some embodiments, substrate 102 is a ceramic-based high temperature co-fired ceramic (HTCC) substrate. Insulation layer 108 is made from a dielectric material (e.g., silicon oxide (SiOₓ) and silicon nitride (SiₓN_{y})). Conductive layers 110n can include aluminum (Al) or other suitable metal(s).

In some embodiments, stack of layers 104 includes alternating layers of insulation material and conductive material. While insulation layer 108 is labeled as a single body structure, insulation layer 108 can be deposited in layers of alternating configuration with conductive layers 110i. Insulation layer 108 can be etched to form trenches. Conductive layer 110a can be deposited in the trenches, which are shaped in the form of conductive traces 110a-j. After the excess material from the deposition of conductive layer 110a is removed, another insulation layer can be deposited over a portion of conductive layer 110a in order to insulate portions of conductive traces 110a-j from additional conductive traces to be stacked thereon. Exposed portions of conductive traces can be coupled to at a later stage of the fabrication process and/or vias can be formed through the stack in order to allow electrical connections to a given layer or to allow electrical connections between conductive traces in different layers. The insulation and conductive material deposition process can be repeated to continue stacking conductive layers over one another while creating an isolation/insulation gap therebetween to prevent undesirable shorts between conductive traces of different conductive layers.

In some embodiments, a top layer 112 of stack of layers 104 includes one or more layers to provide bonding, electronic functionality, and protective coatings. Examples of bonding materials include a solder layer 118 and conductive layer 116. In some embodiments, conductive layer 116 can be an electroless nickel electroless palladium immersion gold (ENEPIG) layer. Examples of protective coatings include conformal coating 120. For electronic functionality, top layer 112 also includes a conductive plane (e.g., a plane of aluminum).

In some embodiments, a bottom layer 114 of stack of layers 104 includes one or more layers of materials to provide electronic functionality and/or bond between stack of layers 104 and substrate 102. Examples of bonding materials include a cohesion metal layer 122, a conductive layer 124, and metal layer 126. In some embodiments, cohesion metal layer 122 can be Si-cohesion metal (e.g., chrome). In some embodiments, conductive layer 124 can be electroless nickel immersion gold (ENIG). And, in some embodiments, metal layer 126 can be tungsten, titanium, aluminum, or another suitable conductor. For electronic functionality, bottom layer 114 also includes a conductive plane (e.g., a plane of aluminum). A benefit of using aluminum is that aluminum is paramagnetic. Skin-depth related losses in aluminum are smaller compared to other conductors. Hence, aluminum can be used for low-loss conductive traces (as will be discussed below).

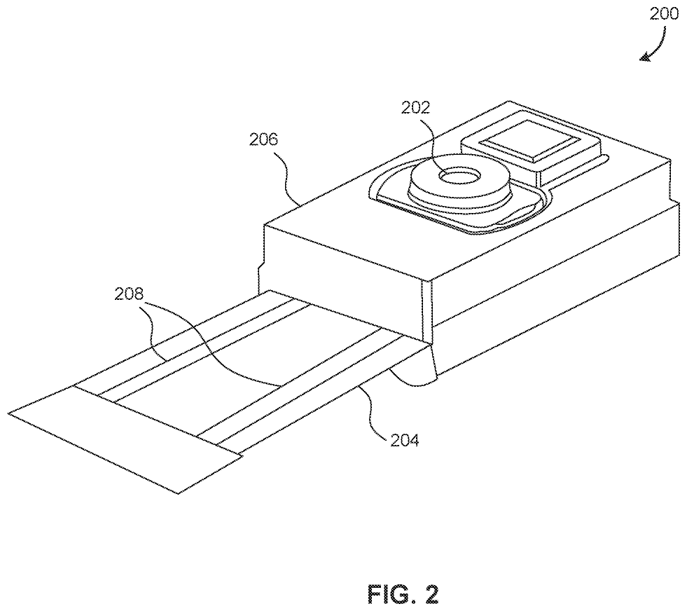

FIG. 2 shows an on-chip camera 200, according to some embodiments. In some embodiments, on-chip camera 200 includes a lens 202, a detector array (not shown, blocked view) disposed behind lens 202, a ribbon cable 204, and packaging 206. Ribbon cable 204 includes one or more wires 208. Alternatively, microcoax cables can be used instead of, or in addition to, ribbon cable 204. The detector array can be an array of photodetector elements that can receive illumination (an image) to generate information signals according to the image.

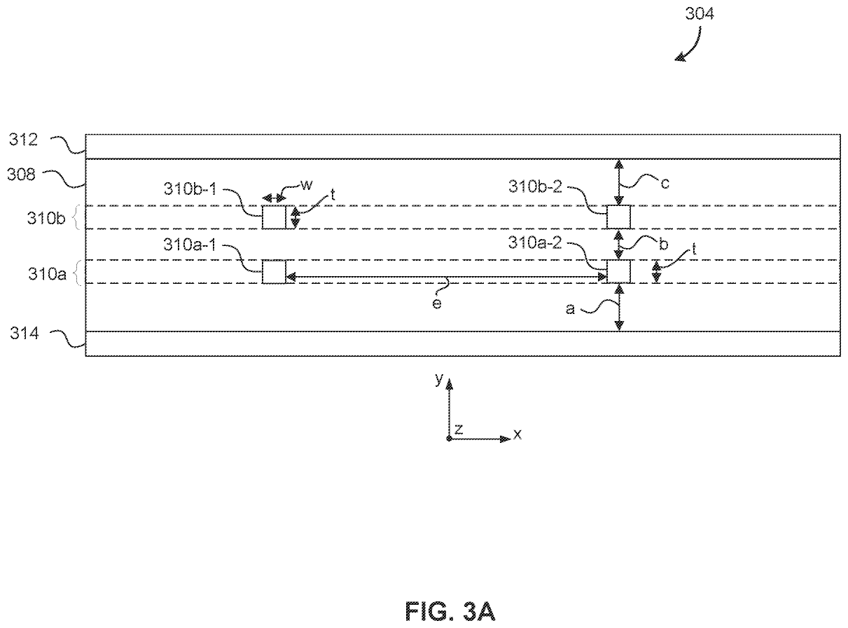

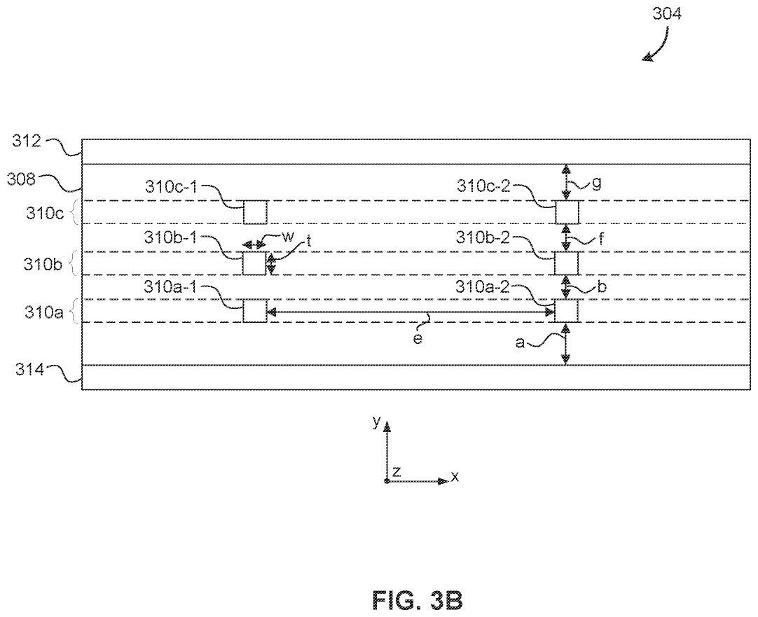

In some embodiments, on-chip camera 200 includes integrated circuit device 100 of FIG. 1, which integrates the detector array and signal routing elements (e.g., conductive traces) of on-chip camera 200. When conductive traces are structured according to one or more of the embodiments herein (e.g., conductive traces 110i-j of FIG. 1 and conductive traces 310i-j of FIGS. 3A and 3B), the operational frequencies for high definition images and high data rates can be achieved while mitigating issues of size reduction constraints, substrate costs, power transmission losses, and parasitic effects.

FIG. 3A shows an illustration of a portion of a stack of layers 304, according to some embodiments. In some embodiments, stack of layers 304 of FIG. 3A can represent a more detailed and/or different view of stack of layers 104 used in integrated circuit device 100 of FIG. 1. The indices i and j in elements of FIG. 3 are used in the same manner as in FIG. 1.

In some embodiments, stack of layers 304 includes an insulation layer 308, conductive layers 310i (e.g., conductive layers 310a and 310b), a top layer 312, and a bottom layer 314. Each of conductive layers 310/includes conductive traces 310i-j (e.g., conductive traces 310a-1, 310a-2, 310b-1, and 310b-2). Unless otherwise noted, the materials, structures, and functions of elements in FIG. 3A are described above with respect to matching elements in FIG. 1 (e.g., elements with reference numbers sharing the two right-most numeric digits).

In some embodiments, FIG. 3A shows an arrangement of conductive traces that can function as a multilayered differential pair. Differential pairs, as opposed to multilayered differential pairs, can be composed of two conductive traces side-by-side and carry substantially equal magnitude (and opposite polarity) signals on each trace. In a multilayered differential pair, each side of the pair is composed of stacked multilayered conductive traces. A first conductive layer (e.g., conductive layer 310a) and a second conductive layer (e.g., conductive layer 310b) are disposed in insulation layer 308. A first conductive trace (e.g., conductive trace 310a-1) of the first conductive layer is stacked with a first conductive trace (e.g., conductive trace 310b-1) of the second conductive layer and run parallel to one another (can run in parallel entirely or in certain sections along a z-direction). Similarly, a second conductive trace (e.g., conductive trace 310a-2) of the first conductive layer is stacked with a second conductive trace (e.g., conductive trace 310b-2) of the second conductive layer. It is to be appreciated, in view of the drawings, that direct contact of the conductive traces is not implied in the term “stacked” (as this would result in electrical shorting). The term “stacked,” in this context, can refer to a vertical or columnar alignment (e.g., along a y-axis) of two or more conductive traces, with the conductive traces being separated by insulation material so as to prevent an electrical short.

In some embodiments, different materials can have different performance characteristics with respect to transmission through an electronic device. For example, undoped silicon and copper can be used as insulation material and conductive material, respectively. However, when placed on a relatively low cost substrate, such as HTCC, the performance of such a device can result in signal losses and non-negligible parasitic effects.

A given selection of materials for insulation layer 308 and conductive layers 310i can result in increased losses and more undesirable coupling between signal-carrying structures (e.g., parasitics). Finding a suitable selection of materials for insulation layer 308 and conductive layers 310i can be challenging. This is because each metal and insulating/dielectric material has unique electron/ion characteristics (e.g., having different bandgaps, impedance, charge carrier velocity, charge carrier effective mass, charge carrier density, phonon resonances, etc.), resulting in unpredictable dispersion characteristics. The loss tangent of the frequency dependent complex permittivity/permeability of the signal-carrying structures can vary substantially depending on the materials used. Furthermore, losses and undesirable coupling are enhanced as frequencies increase and as conductive elements are made smaller and more closely spaced, due to proximity.

The embodiments disclosed herein address the above challenges and describe combinations of materials that effectively work with low cost ceramic substrates, ultra-high frequencies, and smaller and more closely spaced conductive traces/planes. The identified materials have desirable dispersion characteristics that allow the small and closely spaced conductive traces to transmit ultra-high frequency signals without the drawback of non-conforming signal losses and parasitic contributions. The material of insulation layer 308 is silicon dioxide, according to some embodiments. The material of conductive layers 310i and conductive traces 310i-j is aluminum, according to some embodiments. These materials can allow the layers of stack of layers 304, and the conductive traces therein, to be constructed very thin (e.g., about 5 μm to about 10 μm) while having dispersion characteristics that retain transmission of ultra-high frequencies with low losses and low parasitics, even when disposed over a HTCC substrate. Furthermore, electroplating is an important feature for reliable use of HTCC technology. Silicon dioxide thin film on HTCC substrates eliminates various parasitics, such as electroplating tie bars on high current and high frequency signal lines.

In some embodiments, conductive layers 310i can have a thickness t that is about 5 μm to about 10 μm (e.g., about 7 μm). A “thickness” of a layer is defined perpendicular to a plane defined by the layer (in FIG. 3A, thickness is defined along the y-axis). The thickness ranges disclosed herein have a technical significance. For example, if thickness/is greater than about 10 μm, then performance of transmission lines can deteriorate due to worsened impedance mismatch. Conversely, if thickness/is less than about 5 μm, then adhesion strength can deteriorate. A distance a between bottom layer 314 and first conductive layer 310a is about 10 μm to about 15 μm (e.g., about 12 μm). Bottom layer 314 can be a conductive plane. A distance b between first conductive layer 310a and second conductive layer 310b is about 5 μm to about 10 μm (e.g., about 8 μm). A distance c between first conductive layer 310a and top layer 312 is about 10 μm to about 15 μm (e.g., about 12 μm). The full thickness of insulation layer 308 can be considered as having sublayers of dielectric films with thicknesses a, b+t, and c (e.g., as disclosed in method 700, insulation layer 308 can be fabricated by stacking multiple thin films). The number of sublayers can be different depending on how many traces are stacked (e.g., in FIG. 3B, the sublayer thicknesses are a, b+t, f+t, and g). If a thickness of a sublayer of thin film is less than about 5 μm, then the structure of the thin film can be more sensitive to the uncertainties of thin film growth/deposition, thereby affecting the reliability of the thin film. If a thickness of a sublayer is greater than about 12 μm, then the benefits of low loop inductance (described further below) begin to diminish, though sublayer thicknesses of up to about 15 μm still perform reliably.

In some embodiments, a width w of a conductive trace (e.g., conductive trace 310b-1) is about 5 μm to about 10 μm (e.g., about 7 μm). A distance e between a stack of first conductive traces (e.g., conductive traces 310a-1 and 310b-1) and a stack of second conductive traces (e.g., conductive traces 310a-2 and 310b-2) is about 80 μm to about 120 μm (e.g., about 100 μm). A multilayered differential pair can be described as having two elements—a first one of the pair and a second one of the pair. The first one of a multilayered differential pair can be the “left” stack of conductive traces 310a-1 and 310b-1 and the second one of the multilayered differential pair can be the “right” stack of conductive traces 310a-2 and 310b-2, or vice versa. The separation between the first one and the second one of the multilayered pair (distance e) can be larger than a distance between layers (e.g., larger than distances a, b, or c), for example, larger by about two times or more, about five times or more, or about ten times or more.

In some embodiments, a change in magnetic flux inside a closed loop formed by two or more conductive traces 310i-j or by one or more conductive traces 310i-j and signal return paths (e.g., a ground plane, such as top layer 312 or bottom layer 314) can cause loop inductance. A method to reduce loop inductance is by reducing a separation between two or more conductive traces 310i-j or between one or more conductive traces 310i-j and signal return paths to below about 15 μm. By reducing loop inductance, it is possible to reduce the magnetic field lines (flux) forming loops from source to signal ground. Magnetic flux contributes to near field electromagnetic interference (EMI) in both conductive and radiative forms. HTCC technology does not work well with dielectric separations of less than about 40 μm between signals and a nearest ground return path in the substrate. However, using the features of embodiments described herein, this constraint can be overcome. For example, by using silicon dioxide as the insulating material and aluminum as the material for conductive traces, the resulting dispersion characteristics allow dielectric separations of signal-carrying structures to be reduced below about 40 μm, and yet perform well at ultra-high. Furthermore, a parylene thin film conformal coating can be applied to silicon dioxide on HTCC substrates to protect against moisture, while retaining desirable electrical performance features, such as signal transmission at ultra-high frequencies with low losses and low parasitics.

FIG. 3B shows an illustration a portion of stack of layers 304, according to some embodiments. In some embodiments, whereas FIG. 3A shows a multilayered differential pair having two layers of conductive traces, FIG. 3B shows a multilayered differential pair having three layers of conductive traces.

In some embodiments, in addition to the elements that were introduced in FIG. 3A, stack of layers 304 also includes a third conductive layer (e.g., conductive layer 310c) disposed in insulation layer 308. A first conductive trace (e.g., conductive trace 310c-1) of the first conductive layer is stacked with first conductive traces (e.g., conductive trances 310a-1 and 310b-1) of the first and second conductive layers (at least portions of the stacked traces run parallel along a z-direction). Similarly, a second conductive trace (e.g., conductive trace 310c-2) of the third conductive layer is stacked with first and second conductive traces (e.g., conductive traces 310a-2 and 310b-2) of the first and second conductive layers.

In some embodiments, the thickness t of conductive layers 310i, width w, and distances a, b, and e are as described above. A distance f between second conductive layer 310b and third conductive layer 310c is about 5 μm to about 10 μm (e.g., about 8 μm). A distance g between third conductive layer 310c and top layer 312 is about 5 μm to about 10 μm (e.g., about 8 μm). Top layer 312 can be a conductive plane. For a given device for transmission of high speed signals, a change in the type of insulation and conductive material can adversely impact the performance of the device. Whereas it is possible to design conductive layers with the compact dimensions described in reference to FIGS. 3A and 3B for a given combination of insulation and conductive materials (e.g., SiO₂ and aluminum), looking to other combinations of materials is not straightforward and can lead to time-consuming investigation of signal transmission performance. Furthermore, not all material combinations can preserve the compactness of conductive traces without adverse impact to the metrics of signal power loss and parasitic effects.

In some embodiments, using the parameters disclosed for the conductive traces in FIGS. 3A and 3B and assuming a HTCC substrate 102, a two-layer differential pair (e.g., of FIG. 3A) can result in a reduction of insertion loss (less loss is better). For example, at 30 GHz, the insertion loss using the dual-layer conductive trace configuration shown in FIG. 3A is reduced by about 30% compared to a single-layer conductive trace configuration (e.g., insertion loss reduced from about 5.6 dB to about 4.0 dB). At 30 GHz, the insertion loss using the triple-layer conductive trace configuration shown in FIG. 3B is reduced by about 40% compared to a single-layer conductive trace configuration (e.g., insertion loss reduced from about 5.7 dB to about 3.5 dB). At other frequencies, the insertion loss can be reduced as follows. At about 5 GHz, the insertion loss using the dual-layer conductive trace configuration shown in FIG. 3A is reduced by about 30% compared to a single-layer conductive trace configuration (e.g., insertion loss reduced from about 2.3 dB to about 1.6 dB). At about 5 GHz, the insertion loss using the triple-layer conductive trace configuration shown in FIG. 3B is reduced by about 35% compared to a single-layer conductive trace configuration (e.g., insertion loss reduced from about 2.3 dB to about 1.5 dB). At about 10 GHz, the insertion loss using the dual-layer conductive trace configuration shown in FIG. 3A is reduced by about 30% compared to a single-layer conductive trace configuration (e.g., insertion loss reduced from about 3.2 dB to about 2.3 dB). At about 10 GHz, the insertion loss using the triple-layer conductive trace configuration shown in FIG. 3B is reduced by about 35% compared to a single-layer conductive trace configuration (e.g., insertion loss reduced from about 3.2 dB to about 2.1 dB).

In some embodiments, the performance of multilayered differential conductive traces can be characterized from the viewpoint of reflection loss (less loss is better). At about 5 GHz, the reflection loss using the dual-layer conductive trace configuration shown in FIG. 3A is reduced by about 10% compared to a single-layer trace configuration (e.g., reflection loss reduced from about 26.6 dB to about 24.1 dB). At about 5 GHz, the reflection loss using the triple-layer conductive trace configuration shown in FIG. 3B is reduced by about 45% compared to a single-layer conductive trace configuration (e.g., reflection loss reduced from about 26.6 dB to about 15.0 dB). At about 10 GHz, the reflection loss using the dual-layer conductive trace configuration shown in FIG. 3A is reduced by about 20% compared to a single-layer conductive trace configuration (e.g., reflection loss reduced from about 32.1 dB to about 24.9 dB). At about 10 GHz, the reflection loss using the triple-layer conductive trace configuration shown in FIG. 3B is reduced by about 50% compared to a single-layer conductive trace configuration (e.g., reflection loss reduced from about 32.1 dB to about 15.7 dB). At about 30 GHz, the reflection loss using the dual-layer conductive trace configuration shown in FIG. 3A is reduced by about 20% compared to a single-layer conductive trace configuration (e.g., reflection loss reduced from about 39.0 dB to about 30.2 dB). At about 30 GHz, the reflection loss using the triple-layer conductive trace configuration shown in FIG. 3B is reduced by about 40% compared to a single-layer trace configuration (e.g., reflection loss reduced from about 39.0 dB to about 22.6 dB).

In some embodiments, the performance of multilayered differential conductive traces can be characterized from the view point of “eye height” and data frequency (as opposed to pure frequency). Eye diagrams (e.g., generated via an oscilloscope) can be used to characterize systems, evaluating products, and debugging system level issues and are useful for determining the cause of data-related failure from an electrical perspective (e.g., bit errors, lost data packets, and incorrect receiver termination). From an eye diagram, the insertion loss of a transmission medium (e.g., differential pair) can be inferred from a parameter called “eye height” (a larger value is better). Low eye height can be caused by insertion loss (IL) of the transmission media. At a data rate of about 30 Gbps, the eye height using the dual-layer conductive trace configuration shown in FIG. 3A is increased by about 40% compared to a single-layer conductive trace configuration (e.g., eye height increased from about 120 mV to about 170 mV), which translates to a commensurate reduction of data error/loss. At a data rate of about 30 Gbps, the eye height using the triple-layer conductive trace configuration shown in FIG. 3B is increased by about 50% compared to a single-layer conductive trace configuration (e.g., eye height increased from about 120 m V to about 190 mV).

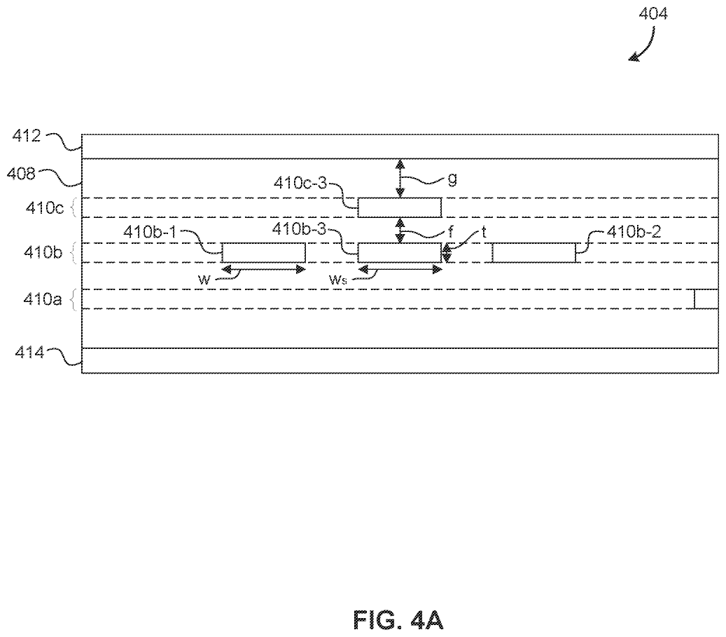

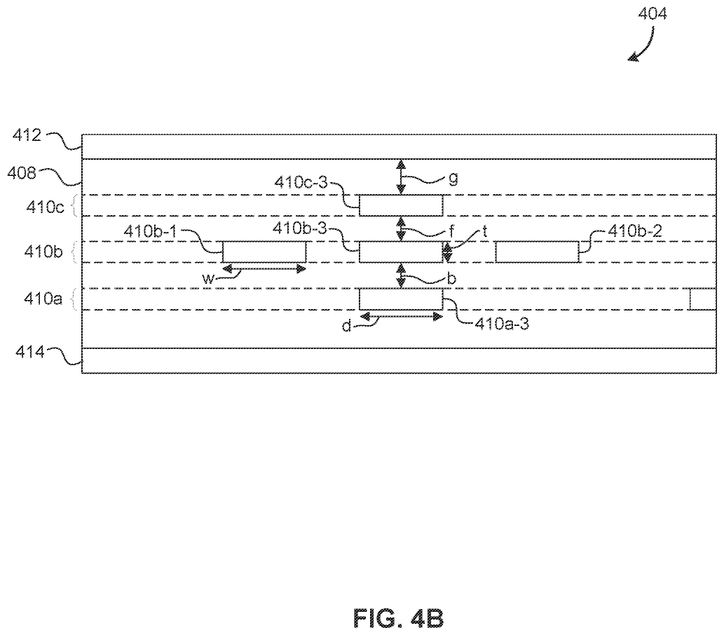

FIG. 4A shows an illustration of a portion of a stack of layers 404, according to some embodiments. In some embodiments, stack of layers 404 of FIG. 4A can represent a more detailed and/or different view of stack of layers 104 used in integrated circuit device 100 of FIG. 1. The indices i and/in some elements of FIG. 4A are used in the same manner as in FIGS. 1, 3A, and 3B.

In some embodiments, FIG. 4A illustrates conductive traces that can be used as shielding to prevent unwanted transfer of signals between two conductive traces (e.g., cross talk). Stack of layers 404 includes an insulation layer 408, conductive layers 410/(e.g., conductive layers 410a, 410b, and 410c), a top layer 412, and a bottom layer 414. Each of conductive layers 410i includes conductive traces 410i-j (e.g., conductive traces 410b-1, 410b-2, 410b-3, 410c-1, and 410c-2). Unless otherwise noted, the materials, structures, and functions of elements in FIG. 4A are as described above with respect to matching elements in FIGS. 1, 3A, and 3B (e.g., elements with reference numbers sharing the two right-most numeric digits).

In some embodiments, a first conductive layer (e.g., conductive layer 410b) and a second conductive layer (e.g., conductive layer 410c) are disposed in insulation layer 408. The first conductive layer includes a first conductive trace (e.g., conductive 410b-1), a second conductive trace (e.g., conductive trace 310b-1), and a shield conductive trace 410b-3. First and second conductive traces 410b-1 and 410b-2 of first conductive layer 410b are configured to transmit electrical signals. Shield conductive trace 410b-3 of first conductive layer 410b is disposed between first and second conductive traces 410b-1 and 410b-2. Shield conductive trace 410b-3 acts as shielding to mitigate cross talk between first and second conductive traces 410b-1 and 410b-2.

In some embodiments, a shield conductive trace 410c-3 of second conductive layer 410c is stacked with shield conductive trace 410b-3 of first conductive layer 410b. The stack of shield conductive traces 410b-3 and 410-c is disposed between first and second conductive traces 410b-1 and 410b-2. The presence of a stacked additional conductive trace provides additional cross talk reduction that is superior to a configuration that uses a single shield conductive trace.

In some embodiments, a thickness t of conductive layers 410i, a width w, and distances f and g are described in reference to FIGS. 3A and 3B. Alternatively, a width w of a conductive trace can be between about 20 μm and about 40 μm (e.g., about 30 μm). A width wₛ of a shield conductive trace can be substantially the same as width w (e.g., between about 20 μm and about 40 μm) or a different width.

FIG. 4B shows an illustration a portion of stack of layers 404, according to some embodiments. In some embodiments, whereas FIG. 4A showed a multilayered shield conductive traces having two layers of shield conductive traces, FIG. 4B shows a multilayered shield conductive trace having three layers of shield conductive traces.

In some embodiments, the stack of shield conductive traces 410b-3 and 410-c is disposed between first and second conductive traces 410b-1 and 410b-2. The presence of a stacked additional conductive trace provides additional cross talk reduction that is superior to a configuration that uses one or two shield conductive traces. Whereas it is possible to design conductive layers with the compact dimensions described in reference to FIGS. 4A and 4B for a given combination of insulation and conductive materials (e.g., SiO₂ and aluminum), looking to other combinations of materials is not straightforward and can lead to time-consuming investigation of the impact to signal transmission performance. Furthermore, not all material combinations can preserve the compactness of conductive traces without adverse impact to the metrics of signal power loss and parasitic effects.

In some embodiments, using the parameters disclosed for the conductive traces in FIGS. 4A and 4B and assuming a HTCC substrate 102, the multilayered shield conductive traces (e.g., of FIGS. 4A and 4B) can result in a reduction of mutual impedance (a lower value is better; a zero value indicates elimination of coupling). Reducing undesirable coupling reduces parasitic effects. For example, at 30 about GHz, the mutual impedance between two signal conductive traces with a dual-layered shield conductive trace therebetween (e.g., of FIG. 4A) is reduced by about 50% compared to a single-layer shield trace configuration (e.g., mutual impedance reduced from about 0.05 Ohm to about 0.03 Ohm). At about 30 GHz, the mutual impedance between two signal conductive traces with a triple-layered shield conductive trace therebetween (e.g., of FIG. 4A) is reduced by about 100% compared to a single-layer shield conductive trace configuration (e.g., mutual impedance reduced from about 0.05 Ohm to about 0 Ohm)—thus eliminating mutual impedance.

In some embodiments, the performance of multilayered differential conductive traces can be characterized from a far-end cross talk (FEXT) and a near-end cross talk (NEXT) (a lower value is better), which can be measured in intensity (e.g., in mV). At about 30 GHz, the FEXT between two signal conductive traces with a dual-layered shield conductive trace therebetween (e.g., of FIG. 4A) is reduced by about 40% compared to a single-layer shield conductive trace configuration (e.g., FEXT reduced from about 6.2 m V to about 3.7 mV). At about 30 GHz, the NEXT between two signal conductive traces with a dual-layered shield conductive trace therebetween (e.g., of FIG. 4A) is reduced by about 40% compared to a single-layer shield conductive trace configuration (e.g., FEXT reduced from about 5.4 m V to about 3.3 m V). At about 30 GHz, the FEXT between two signal conductive traces with a triple-layered shield conductive trace therebetween (e.g., of FIG. 4B) is reduced by about 100% compared to a single-layer shield trace configuration (e.g., FEXT reduced from about 6.2 m V to about 0 m V)—thus eliminating cross talk. At about 30 GHz, the NEXT between two signal conductive traces with a triple-layered shield conductive trace therebetween (e.g., of FIG. 4B) is reduced by about 100% compared to a single-layer shield conductive trace configuration (e.g., FEXT reduced from about 5.4 m V to about 0 m V)—thus eliminating cross talk.

FIGS. 5A and 5B show illustrations of various electronic elements, according to some embodiments. In some embodiments, one or more of the electronic elements of FIG. 5A can be connected to conductive traces in stack of layers 104, 304, or 404, as well as those within on-chip camera 200, as described in reference to FIGS. 1, 2, 3A, 3B, 4A, and 4B.

In some embodiments, the electronic elements include resistors, capacitors, inductors, transistors, diodes, ferrites/multiferroics, passive devices, and active devices. In particular, FIG. 5A shows examples of a ferrite 502 and a capacitor 504, which can be used for conductive and radiative noise suppression. Ferrite 502 can be of a type that is compatible with integrated circuit printing processes, such as a thin-film multiferroic ferrite. Ferrite 502 can have inductance properties. Ferrite 502 includes a thin film of multiferroic material 509 and conductive trace 507 having a meander pattern. Capacitor 504 can be a ferroelectric capacitor based on multiferroic material. Capacitor 504 can be of a type that is compatible with integrated circuit printing processes. Ferrite 502 and capacitor 504 can each have an input terminal 506 and an output terminal 508. Tunable elements, such as capacitor 504 (e.g., a tunable capacitor), can include another terminal 510 for tuning (e.g., tuning via V-DC voltage). Multiferroic elements, such as ferrite 502 and capacitor 504, can be implemented for high-performance ultra-high frequency signal transmission in integrated circuits (e.g., can be used as high frequency noise suppressors).

In FIG. 5A, different views of capacitor 504 are shown. For capacitor 504 shown on the left, details of the capacitive structure are shown (e.g., interdigitated traces 511 that function as capacitor plates and thin film of multiferroic material 509). For capacitor 504 shown on the right, shapes of the bond pad structures for input terminal 506 and output terminal 508 are shown.

In FIG. 5B, ferrite 502 and capacitor 504 are shown as discrete elements mounted on substrate 102 with stack of layers 104 of FIG. 1. Ferrite 502 and/or capacitor 504 can be coupled to conductive traces in stack of layer 104 via accessible portions of top layer 112. Input terminal 506, output terminal 508, and/or terminal 510 can be bonded to exposed portions of conductive layer 116 or solder layer 118, or vias can be created to form connections with deeper conductive traces in the layers. Multiferroic elements, such as ferrite 502 and capacitor 504, can have excellent signal processing performance (e.g., ultra-high frequencies with low losses and low parasitics), but a poor performing substrate can be the bottleneck that prevents taking full advantage of the capabilities of the multiferroic elements. By mounting ferrite 502 and capacitor 504 on substrate 102 disclosed herein (e.g., with stack of layers 104, 304, or 404 of FIGS. 1, 3, and 4), such a bottleneck can be mitigated.

Input terminal 506, output terminal 508, and terminal 510 can be structured as bond pads (e.g., ball grid array (BGA) pads for packaging) or can be integrated and connected to other parts of the integrated circuit via conductive traces. One of more features of the electronic elements disclosed herein, such as ferrite 502 and capacitor 504, can be deposited onto a substrate, meaning they can be integrated elements of an integrated circuit, thereby allowing for smaller footprint and desirable performance characteristics compared to discrete elements.

In some embodiments, ferrite 502 and/or capacitor 504 can be a class of circuit elements known as ferrites or multiferroics. Embodiments directed to stack of layers 104, 304, or 404 in FIGS. 1, 3A, 3B, 4A, and 4B are suitable for integrating ferrite passive/active elements onto HTCC substrates. Multiferroic thin film materials can function as ferroelectric and ferromagnetic or ferromagnetic materials. Integrated ferrite elements are suitable for a wide range of frequencies, including those above S GHz. Thin film materials, such as bismuth ferrous oxide or barium strontium titanate, can be used to form tunable ferroelectric capacitors and ferrites that operate at ultra-high frequencies (UHF). High frequency thin film and spinel ferrites can be deposited on silicon dioxide surfaces. Ferrite 502 can be a ferrite-metal-based inductor (e.g., conductive trace 507 is a metal and multiferroic material 509 is a ferrite).

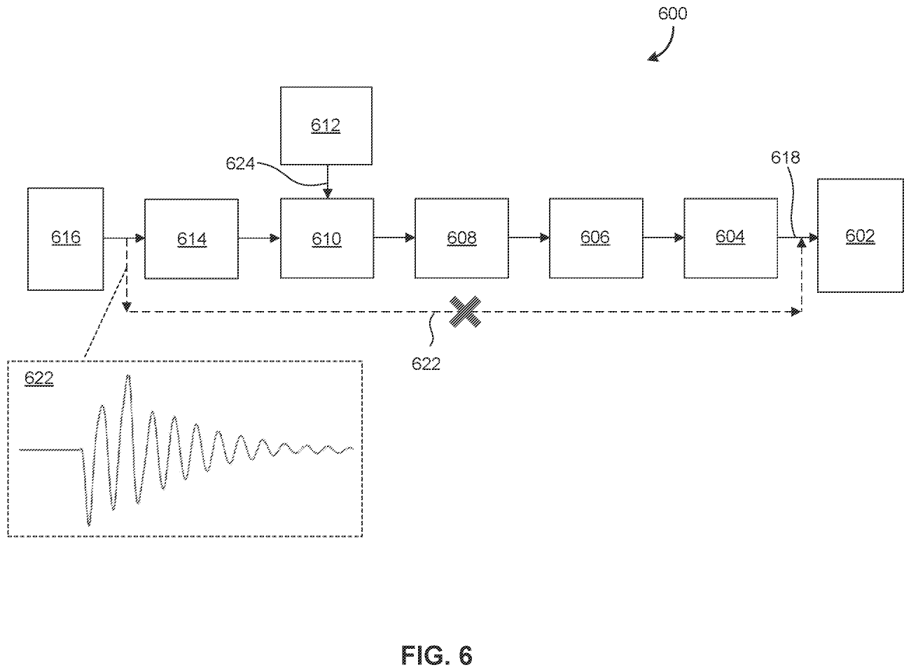

FIG. 6 illustrates block diagrams of elements of a noise filter 600, according to some embodiments. In some embodiments, noise filter 600 includes a system power supply 602, a mid-frequency ferrite 604, a capacitor 606, a high frequency ferrite 608, a tunable ferroelectric capacitor 610, a controller 612, an ultra-broadband ferrite 614, and a pulse generator 616. Pulse generator 616 generates a signal 618 for sending to system power supply 602. Signal 618 can be an ultra-high frequency signal (e.g., greater than about 5 GHz).

In some embodiments, signal 618 is transmitted through various stages of noise filter 600. The various stages of noise suppression elements can be integrated multiferroic elements. Noise filter 600 includes integrated circuit elements and discrete elements. Tunable ferroelectric capacitor 610 is an integrated element and has the structure of capacitor 504 of FIGS. 5A and 5B, according to some embodiments. Controller 612 generates a control signal 624 to control a voltage at terminal 510 of FIGS. 5A and 5B and, therefore, tune tunable ferroelectric capacitor 610. Ultra-broadband ferrite 614 is an integrated element and has the structure of ferrite 502 of FIGS. 5A and 5B for suppressing ultra-high frequency noise (e.g., 5 GHz or greater), according to some embodiments. Mid-frequency ferrite 604, capacitor 606, and high frequency ferrite 608 can be discrete or integrated elements.

In some embodiments, as signal 618 is transmitted through transmission lines of noise filter 600, noise signal 622 can be generated due to impedance mismatch, losses at the transmission lines, and/or parasitic effects caused by a suboptimal design of conductive traces. Noise signal 622 can be a pulse ripple having one or more frequencies associated with the ultra-high frequency of signal 618. Noise signal 622 causes electromagnetic interference (EMI) by superimposing itself onto signal 618, thereby contributing EMI noise at system power supply 602. In embodiments in which system power supply is a shared central system power supply, it is preferred that system power supply 602 produce as little noise as possible so as not to adversely impact upstream electronics. Noise filter 600 is suitable for the implementation of a low-noise power supply by using multiferroics and tunable ferroelectric capacitors, such as ferrite 502 and capacitor 504.

In some embodiments, the impedance characteristics of stack of layers 104/304/404 of FIGS. 1, 3A, 3B, 4A, and 4B are conducive for suppressing noise signal 622. As described above regarding reduction of signal losses and parasitic effects of stack of layers 104/304/404, implementing the elements of noise filter 600 on substrate 102/302/402 having stack of layers 104/304/404 of FIGS. 1, 3A, 3B, 4A, and 4B can prevent leakage of energy from signal 618 into surrounding structures (e.g., by preventing loss and undesirable inductive coupling between unrelated structures). As more energy is conserved in signal 618, less energy is contributed to the formation of noise signal 622.

The performance features of HTCC with a thin dielectric layer, such as silicon dioxide, are not limited to electrical integrated circuits, but can also be extended to integrated optics.

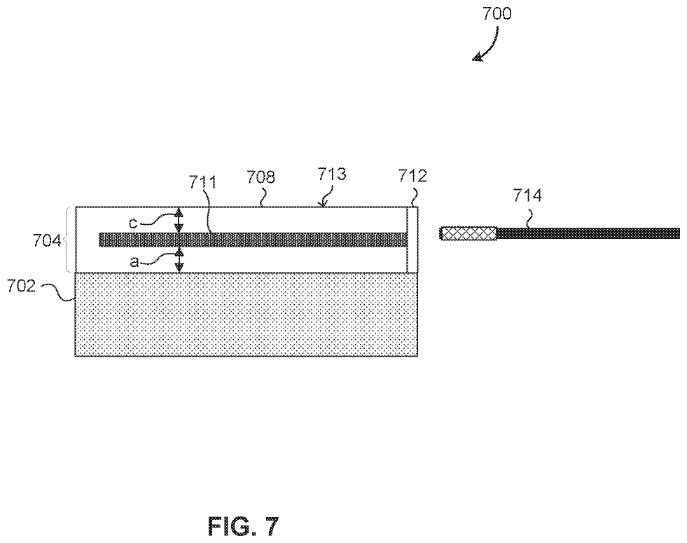

FIG. 7 illustrates an integrated waveguide device 700, according to some embodiments. In some embodiments, integrated waveguide device 700 includes a ceramic-based substrate 702 and a stack of layers 704. Stack of layers 704 includes a first dielectric layer 708 and a second dielectric layer 711. Ceramic-based substrate 702 is a HTCC substrate, which is relatively low-cost (e.g., compared to LTCC). Selection of materials for integrated waveguide device 700 can be similar to examples described in reference to FIGS. 3A, 3B, 4A, and 4C. First dielectric layer 708 has a first refractive index. First dielectric layer 708 can be made of silicon dioxide, which has a refractive index of about 1.4 to about 1.6. Second dielectric layer 711 has a second refractive index. Second dielectric layer 711 can be made of silicon nitride, which has a refractive index of about 1.9 to about 3.0. The second refractive index is higher than the first refractive index. With the refractive index of second dielectric layer 711 being higher than that of its surrounding (e.g., refractive index of first dielectric layer 708), the conditions for total internal reflection (TIR) are met and integrated waveguide device 700 can function as a waveguide for transmitting illumination. TIR is the phenomenon in which light travelling within second dielectric layer 711, arriving at an interface between second dielectric layer 711 and first dielectric layer 708, are not refracted into first dielectric layer 708, but completely reflected back into second dielectric layer 711. It occurs if first dielectric layer 708 has a higher wave speed (lower refractive index) than second dielectric layer 711, and the propagating light is incident at a sufficiently oblique angle on the interface.

In some embodiments, a thickness of second dielectric layer 711 is about 10 μm to about 20 μm (e.g., about 15 μm). A distance a from second dielectric layer 711 to ceramic-based substrate 702 is about 10 μm to about 20 μm (e.g., about 15 μm). A distance b from second dielectric layer 711 to a surface 713 that is opposite ceramic-based substrate 702 is about 10 μm to about 20 μm (e.g., about 15 μm).

Similar to how stack of layers 104, 304 and 404 of FIGS. 1, 3A, 3B, 4A, and 4B transmit electrical signals at ultra-high frequency with low losses and low parasitics, integrated waveguide device 700 can transmit optical signals with ultra-high frequency modulation (e.g., greater than 50 GHz) with low losses and low parasitics by using the structures described herein. Stack of layers 704 can be integrated as described previously with respect to stack of layers 104, 304 and 404 of FIGS. 1, 3A, 3B, 4A, and 4B. For example, first dielectric layer 708 can be etched to form trenches. Second dielectric layer 711 can be deposited in the trenches, which can be shaped, arranged, and sized similar to conductive traces 110i-j, 310i-j, and/or 410i-j of FIGS. 1, 3A, 3B, 4A, and 4B.

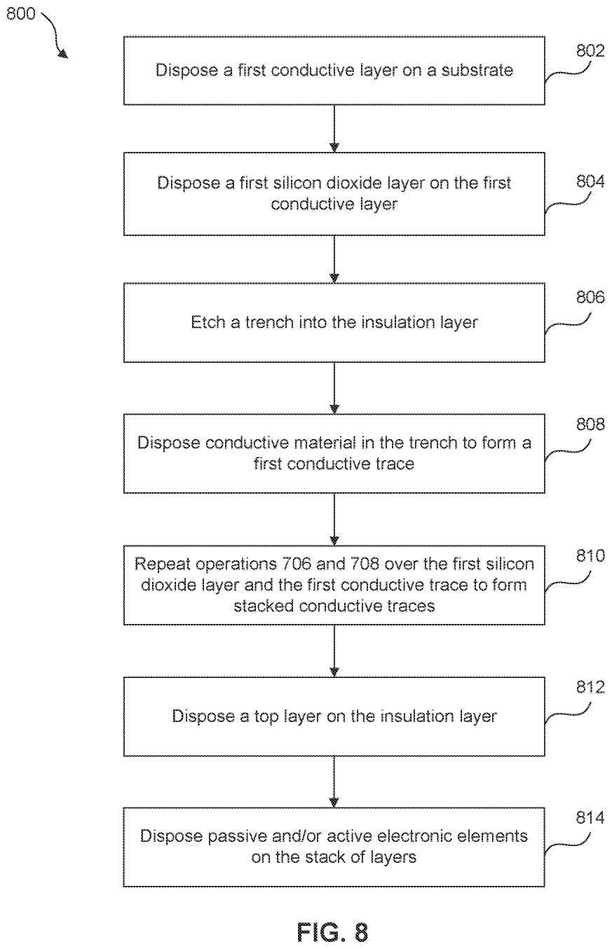

In some embodiments, stack of layers 704 can be implemented together with stack of layers 104, 304 and 404 of FIGS. 1, 3A, 3B, 4A, and 4B (e.g., on the same substrate). For example, silicon dioxide can be used for insulation layer 108/308/408 of FIGS. 1, 3A, 3B, 4A, and 4B, as well as first dielectric layer 708. As will be described below in reference to FIG. 8, thin films of silicon dioxide can be stacked multiple times. In between each stacking, aluminum can be stacked in between applications of silicon dioxide layers to form conductive layers 110i/310i/410i of FIGS. 1, 3A, 3B, 4A, and 4B or silicon nitride can be stacked in between applications of silicon dioxide layers to form waveguides. Implementing both conductive traces and waveguides on the same substrate can be achieved by depositing aluminum at a region of substrate 102/302/402/702 and depositing silicon nitride at a different region of substrate 102/302/402/702.

In some embodiments, integrated waveguide device 700 includes a coupling interface 712. Coupling interface 712 is connected to a lateral edge of stack of layers 704. Coupling interface 712 provides external optical coupling with an optical fiber 714. Coupling interface 712 allows light to propagate in and/or out of stack of layers 704. Optical fiber 714 can launch light into, and/or receive light from, stack of layers 704 via coupling interface 712. Optical fiber 714 can be a metalized (e.g., gold plated) optical fiber. Coupling interface 712 can be structured as a precision v-groove with metalized castellation for connecting with optical fiber 714.

In some embodiments, the structures described herein for transmitting signals (e.g., conductive traces, waveguides, and electronic elements) are capable of operating at ultra-high frequencies, for example, about 5 GHz or more, about 10 GHz or more, about 15 GHz or more, about 20 GHz or more, about 30 GHz or more, about 50 GHz or more, about 80 GHz or more, and about 100 GHz or more.

FIG. 8 shows a flowchart of a method 800 for fabricating stack of layers 104, 304, 404, and/or 704 of FIGS. 1, 3A, 3B, 4A, 4B, and 7, according to some embodiments. Additional operations can be performed between various operations of method 800 and can be omitted for clarity and ease of description. The additional operations can be provided before, during, and/or after method 800, in which one or more of these additional operations are briefly described herein. Moreover, it may not be needed to perform all of the operations. Additionally, some of the operations may be performed simultaneously or in a different order than shown in FIG. 8. In some embodiments, one or more other operations may be performed in addition to or in place of the presently described operations.

In some embodiments, stack of layers 104/304/404/704 is disposed on ceramic-based substrate 102/302/402/702. At operation 802, bottom layer 114/314/414 (e.g., a first conductive layer) is disposed on substrate 102/302/402. This can be achieved via a suitable material deposition or growth technique (e.g., vapor deposition and thin-film growth). The arrangement of layers within bottom layer 114/314/414 can be as described above with respect to cohesion metal layer 122, conductive layer 124, and/or metal layer 126.

In some embodiments, at operation 804, insulation material for insulation layer 108/308/408 is disposed on bottom layer 114/314/414. This can be achieved via a suitable material deposition or growth technique. In the case of waveguide device 700, first dielectric layer 708 is disposed on ceramic-based substrate 702, but can also be disposed on bottom layer 114/314/414 if present (e.g., insulation layer 108/308/408 can be first dielectric layer 708). In some embodiments, a first silicon dioxide layer (e.g., a fraction or a portion of insulation/dielectric layer 108/308/408/708) is provided at operation 804 in preparation for receiving conductive or waveguide material. Additional material for insulation/dielectric layer 108/308/408/708 (e.g., one or more additional silicon dioxide layers) can added at later operations.

In some embodiments, at operation 806, a trench is etched into the portion of insulation/dielectric layer 108/308/408/708. This can be achieved via a suitable pattern printing process (e.g., lithography using a mask and photoresist).

In some embodiments, at operation 808, conductive material for conductive layer 110a/310a/410a is disposed in the trench to form conductive traces 110a-j/310a-j/410a-j. For waveguides, dielectric material for second dielectric layer 711 is disposed in the trench to form the light propagation medium of one or more waveguides. The disposition of materials can be achieved via a suitable material deposition or growth technique. Excess materials outside of the trench can then be removed (e.g., if a mask is present, remove the mask along with excess materials).

In some embodiments, at operation 810, the operations described for operations 806 and 808 can be repeated over the existing insulation/dielectric layer and conductive layers (or waveguides) to continue stacking more silicon dioxide layers for insulation layer 108/308/408 and additional conductive layer(s) 110i/310i/410i to form stacked conductive traces 110i-j/310i-j/410i-j (or waveguides).

In some embodiments, at operation 812, top layer 112/312/412 (e.g., a second conductive layer) is disposed on insulation/dielectric layer 108/308/408/708. This can be achieved via a suitable material deposition or growth technique. The arrangement of layers within top layer 114/314/414 can be as described above with respect to conductive layer 116, solder layer 118, and/or conformal coating 120.

In some embodiments, at operation 814, passive and/or active electronic elements are disposed on or at stack of layers 104/304/404. Electronic elements can include multiferroics as described above with respect to ferrite 502 and capacitor 504. Integrated electronic elements can be formed using a suitable pattern printing technique.

In some embodiments, the arrangements and dimensions of the various structures formed via method 800 can be as described above in reference to FIGS. 1-6.

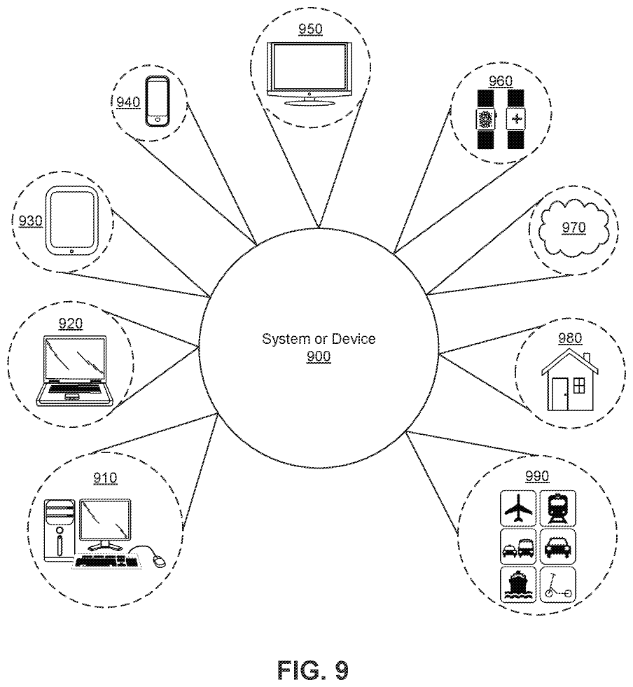

FIG. 9 shows an illustration of exemplary systems or devices that can include the disclosed embodiments. System or device 900 can incorporate one or more of the disclosed embodiments in a wide range of areas. For example, system or device 900 can be implemented in one or more of a desktop computer 910, a laptop computer 920, a tablet computer 930, a cellular or mobile phone 940, and a television 950 (or a set-top box in communication with a television).

Also, system or device 900 can be implemented in a wearable device 960, such as a smartwatch or a health-monitoring device. In some embodiments, the smartwatch can have different functions, such as access to email, cellular service, and calendar functions. Wearable device 960 can also perform health-monitoring functions, such as monitoring a user's vital signs and performing epidemiological functions (e.g., contact tracing and providing communication to an emergency medical service). Wearable device 960 can be worn on a user's neck, implantable in user's body, glasses or a helmet designed to provide computer-generated reality experiences (e.g., augmented and/or virtual reality), any other suitable wearable device, and combinations thereof.

Further, system or device 900 can be implemented in a server computer system, such as a dedicated server or on shared hardware that implements a cloud-based service 970. System or device 900 can be implemented in other electronic devices, such as a home electronic device 980 that includes a refrigerator, a thermostat, a security camera, and other suitable home electronic devices. The interconnection of such devices can be referred to as the “Internet of Things” (IoT). System or device 900 can also be implemented in various modes of transportation 990, such as part of a vehicle's control system, guidance system, and/or entertainment system.

The systems and devices illustrated in FIG. 9 are merely examples and are not intended to limit future applications of the disclosed embodiments. Other example systems and devices that can implement the disclosed embodiments include portable gaming devices, music players, data storage devices, and unmanned aerial vehicles.

It is to be appreciated that the Detailed Description section, and not the Abstract of the Disclosure section, is intended to be used to interpret the claims. The Abstract of the Disclosure section may set forth one or more but not all possible embodiments of the present disclosure as contemplated by the inventor(s), and thus, are not intended to limit the subjoined claims in any way.

Unless stated otherwise, the specific embodiments are not intended to limit the scope of claims that are drafted based on this disclosure to the disclosed forms, even where only a single example is described with respect to a particular feature. The disclosed embodiments are thus intended to be illustrative rather than restrictive, absent any statements to the contrary. The application is intended to cover such alternatives, modifications, and equivalents that would be apparent to a person skilled in the art having the benefit of this disclosure.

The foregoing disclosure outlines features of several embodiments so that those skilled in the art may better understand the aspects of the present disclosure. Those skilled in the art will appreciate that they may readily use the present disclosure as a basis for designing or modifying other processes and structures for carrying out the same purposes and/or achieving the same advantages of the embodiments introduced herein. Those skilled in the art will also realize that such equivalent constructions do not depart from the spirit and scope of the present disclosure, and that they may make various changes, substitutions, and alterations herein without departing from the spirit and scope of the present disclosure,

What is claimed is:

1. An integrated circuit device, comprising:
a ceramic-based substrate;
a stack of layers disposed on the ceramic-based substrate, the stack of layers comprising:
an insulation layer; and
a conductive layer comprising conductive traces; and
electronic elements electrically connected to the conductive layer, wherein the conductive layer is configured to route electrical signals to the electronic elements.

2. The integrated circuit device of claim 1, wherein:
the insulation layer is a silicon dioxide layer; and
the conductive layer is an aluminum layer having a thickness of about 5 microns to about 10 microns.

3. The integrated circuit device of claim 1, wherein:
the conductive layer is a first conductive layer;
the stack of layers further comprises a second conductive layer comprising conductive traces disposed in the insulation layer; and
the second conductive layer is an aluminum layer having a thickness of about 5 microns to about 10 microns.

4. The integrated circuit device of claim 1, wherein the electronic elements comprises an array of photodetector elements configured to receive illumination and to generate information signals according to an image associated with the received illumination, and wherein the conductive traces are configured to transmit the information signals.

5. The integrated circuit device of claim 1, wherein:
the conductive layer is a first conductive layer;
the stack of layers further comprises a second conductive layer comprising conductive traces disposed in the insulation layer;
a first conductive trace of the second conductive layer is stacked with and runs parallel to a first conductive trace of the first conductive layer; and
a second conductive trace of the second conductive layer is stacked with and runs parallel to a second conductive trace of the first conductive layer.

6. The integrated circuit device of claim 5, wherein a separation between the first conductive trace of the first conductive layer and the first conductive trace of the second conductive layer is about 10 microns to about 15 microns.

7. The integrated circuit device of claim 5, wherein:
the stack of layers further comprises a third conductive layer comprising conductive traces disposed in the insulation layer;
a first conductive trace of the third conductive layer is stacked with the first conductive trace of the first conductive layer and the first conductive trace of the second conductive layer, and
a second conductive trace of the third conductive layer is stacked with the second conductive trace of the first conductive layer and the second conductive trace of the second conductive layer.

8. The integrated circuit device of claim 1, wherein:
the conductive layer is a first conductive layer,
the stack of layers further comprises a second conductive layer comprising conductive traces disposed in the insulation layer;
first and second conductive traces of the first conductive layer are configured to transmit signals;
a shield conductive trace of the first conductive layer is disposed between the first and second conductive traces of the first conductive layer; and
a shield conductive trace of the second conductive layer is stacked with the shield conductive trace of the first conductive layer.

9. The integrated circuit device of claim 8, wherein:
a third conductive layer comprising conductive traces disposed in the insulation layer; and
a shield conductive trace of the third conductive layer is stacked with the shield conductive trace of the first conductive layer and the shield conductive trace of the second conductive layer.

10. The integrated circuit device of claim 1, wherein one or more of the electronic elements comprises a tunable ferroelectric capacitor.

11. The integrated circuit device of claim 1, wherein one or more of the electronic elements comprises an integrated ferrite configured to filter noise comprising a frequency component of about 5 GHz or greater.

12. The integrated circuit device of claim 1, wherein the ceramic-based substrate is a high-temperature, co-fired ceramic substrate.

13. The integrated circuit device of claim 1, wherein the stack of layers further comprises a bottom conductive plane disposed between the insulation layer and the ceramic-based substrate.

14. A waveguide device, comprising:
a ceramic-based substrate; and
a waveguide stack disposed on the ceramic-based substrate, the waveguide stack comprising:
a first layer comprising a first dielectric material;
a second layer disposed in the first layer and comprising a second dielectric material different from the first dielectric material and having a refractive index greater than a refractive index of the first dielectric material.

15. The waveguide device of claim 14, wherein the first dielectric material comprises silicon dioxide and the second dielectric material comprises silicon nitride.

16. The waveguide device of claim 14, further comprising a coupling interface configured to propagate light in and/or out of the waveguide stack.

17. The waveguide device of claim 16, wherein a shape of the coupling interface is a v-groove configured to connect with an optical fiber.

18. A method, comprising:
disposing a first conductive layer on a ceramic-based substrate;
disposing a first silicon dioxide layer on the first conductive layer;
etching a trench in the first silicon dioxide layer,
disposing a conductive material in the trench to form a first conductive trace;
disposing a second silicon dioxide layer on the first silicon dioxide layer and the first conductive trace; and
disposing a second conductive layer over the second insulation layer.

19. The method of claim 18, wherein:
disposing the first silicon dioxide layer comprises depositing silicon dioxide at a thickness of about 10 μm to 20 μm; and
disposing the conductive material comprises depositing aluminum at a thickness of about 5 μm to 10 μm.

20. The method of claim 18, wherein disposing the first conductive layer on the ceramic-based substrate comprises disposing the first conductive layer on a high temperature, co-fired ceramic substrate.
